(19) United States
(12) Patent Application Publication
(10) Pub. No.: US 2025/0298308 A1
(43) Pub. Date: Sep. 25, 2025

(54) HYDROPHONE BASED ON NANOSCALE CRACKS AND PREPARATION METHOD THEREFOR

(71) Applicant: DALIAN UNIVERSITY OF TECHNOLOGY, Dalian (CN)

(72) Inventors: Mengxi WU, Dalian (CN); Yuan LAN, Dalian (CN); Mengjing LIU, Dalian (CN); Weiyi LIU, Dalian (CN); Junshan LIU, Dalian (CN)

(21) Appl. No.: 19/230,823

(22) Filed: Jun. 6, 2025

(30) Foreign Application Priority Data
Sep. 19, 2024 (CN) 202411302773.5

(51) Int. Cl. G03F 7/00; C23C 14/20; C23C 14/35; G01V 1/18; G03F 7/16

(52) U.S. Cl. CPC G03F 7/0035; C23C 14/20; C23C 14/35; G01V 1/186; G03F 7/162

(57) ABSTRACT

The present invention provides a hydrophone based on nanoscale cracks and a preparation method therefor, and belongs to the technical field of hydrophones. The method includes: firstly, depositing a layer of metal film on the surface of a flexible polymer, spin coating a layer of photoresist on the surface of the metal film on the flexible polymer, and patterning the photoresist and the metal film; secondly, patterning the photoresist on the metal film again; thirdly, bending the flexible polymer and the metal film to generate nanoscale cracks on the metal film; finally, bonding the flexible polymer, PMMA and a glass sheet together, and sealing after injecting purified water into a cavity to obtain the hydrophone. By bonding a nanoscale crack sensing unit with ultra-high sensitivity and flexibility to a substrate with a cavity, ultra-sensitive detection of low-frequency underwater sounds can be achieved, thereby expanding the detection range of the hydrophone.

### TECHNICAL FIELD

The present invention belongs to the technical field of hydrophones, and relates to a hydrophone based on nanoscale cracks and a preparation method therefor.

### BACKGROUND

Low-frequency underwater acoustic signals have become a frequently-used means for long-distance detection and deep-sea exploration due to the low absorption and long propagation distance in water. Acoustics stealth technique is adopted by some underwater weapons and submarines, with the noise level getting lower and lower, and the noise frequency also decreasing accordingly. Therefore, acquisition and processing of low-frequency underwater acoustic signals in an underwater sound field is a problem that scholars in the fields of marine acoustics and underwater acoustics pay more attention to at present. Underwater acoustic target detection technology is an important research direction in the fields of underwater acoustic signal processing and sonar, and is also one of the core technologies in marine application fields such as environmental perception, target monitoring, resource exploration and information acquisition. Detection of long-distance and stealth targets can be achieved by researchers through analyzing and processing vector information in the underwater sound field, such as particle velocity, acceleration, displacement and sound pressure.

A hydrophone is a device that converts electrical signals into underwater acoustic signals or vice versa, the status of which in sonar is similar to that of an antenna in radio equipment, and is also an acoustic device that transmits and receives sound waves underwater. A transducer that converts acoustic signals into electrical signals and is used for receiving acoustic signals in water is called a receiving transducer, and is also often referred to as a hydrophone. Pressure changes generated underwater can be converted into electrical signals by the hydrophone, and real changes of an underwater low-frequency sound field can be obtained through further analysis and processing of the electrical signals. Low-frequency hydrophones play an extremely important role in national defense and security undertakings.

At present, common sensing units of hydrophones are all prepared on hard substrates, with low sensitivity and relatively complex structures and manufacturing processes. Moreover, such sensing units are usually designed to detect underwater acoustic signals with relatively high frequencies and have weak detection capabilities for low-frequency underwater acoustic signals. No specific application of using a flexible substrate as a sensing unit of a hydrophone to detect low-frequency underwater acoustic signals has been developed yet, and no nanoscale crack hydrophone based on a flexible substrate has been reported at present.

### SUMMARY

In view of the existing problems, the present invention provides a hydrophone based on nanoscale cracks and a preparation method therefor. The hydrophone has a high sensitivity to low-frequency underwater alternating sound pressure. At the same time, by using a layer of metal film on a flexible substrate as a sensing unit, the method does not require processes such as high temperature annealing. The present invention has simple manufacturing process and structure, and has a high sensitivity for low-frequency underwater sounds.

To achieve the above purpose, the present invention adopts the following technical solution:

A preparation method for a hydrophone based on nanoscale cracks is provided, which comprises: step 1, depositing a layer of metal film on the surface of a flexible polymer by a thin film deposition method; step 2, spin coating a layer of photoresist on the surface of the metal film on the flexible polymer, and patterning the photoresist and the metal film; step 3, patterning the photoresist on the metal film again; step 4, bending the flexible polymer and the metal film to generate nanoscale cracks on the metal film, and removing the photoresist adhering to the metal film; step 5, bonding the flexible polymer to laser-cut PMMA and then to a glass sheet, and finally sealing after injecting purified water into a cavity of a hydrophone to complete the preparation of the hydrophone. The method comprises the following specific steps:

Step 1): sputtering a layer of metal film on the surface of a flexible polymer by a thin film deposition method. A substrate of the flexible polymer is made of PDMS, the metal film is made of Au, and the thin film deposition method is a magnetron sputtering method.

Step 2): spin coating a layer of photoresist on the surface of the metal film, and patterning the photoresist and the metal film.

Step 3): patterning the photoresist on the metal film again according to a required density of nanoscale cracks on the metal film; the pattern of the photoresist obtained is horizontally arranged photoresist stripes with the same spacing, and thus a neutral layer between part of the flexible polymer with photoresist and part of the flexible polymer without photoresist is at a different level.

Step 4): bending the flexible polymer along a direction parallel to the photoresist stripes so as to generate nanoscale cracks on the metal film of the flexible polymer. In this step, as part of the flexible polymer is provided with photoresist and part of the flexible polymer is not provided with photoresist, nanoscale cracks are generated on the part of the metal film without photoresist coverage after bending, i.e., due to the protective effect of the photoresist stripes, nanoscale cracks are only generated in a metal film area not covered by the photoresist, thus the locations and densities of the nanoscale cracks are accurately controlled.

Step 5): removing the photoresist on the metal film to obtain a strip-shaped sensing unit with nanoscale cracks, wherein both ends of the strip-shaped sensing unit are provided with electrodes of the sensing unit, and no crack is generated at the electrodes. In this step, for the flexible polymer, after full exposure of the photoresist using a standard photo-lithography technology, the photoresist on the surface of the metal film is removed with a developing solution to obtain the strip-shaped sensing unit with nanoscale cracks.

Step 6): cutting a hole penetrating through a PMMA substrate of the same size as the flexible polymer in the center of the substrate by a laser cutting machine, wherein the shape of the hole is not limited; bonding the flexible polymer to one side of the cut PMMA substrate with a residue-free adhesive tape, and reserving an area unbonded for the convenience of subsequent operations; applying the residue-free adhesive tape to the other side of the cut PMMA substrate; bonding a glass sheet to the other side of the PMMA substrate, at which time, a cavity will be formed in the space left after the PMMA substrate between the flexible polymer and the glass sheet is cut; injecting a liquid into the cavity using a syringe through the above-mentioned unbonded area to balance part of the pressure; bonding edges of the unbonded area with the residue-free adhesive tape again to complete the preparation of the hydrophone.

Further, methods for patterning in the step 2) are a standard photo-lithography process and wet etching. A specific way is as follows: using a UV lithography machine to pattern the photoresist on the flexible polymer, using a 0.5% solution of sodium hydroxide as the developing solution to remove the exposed photoresist and leave the unexposed photoresist as a protective layer, and using a gold-etching solution to remove the unprotected metal film. The photoresist is BP212 positive photoresist.

Further, a method for patterning again in the step 3) is the standard photo-lithography process. A specific way is as follows: after changing a photomask, conducting exposure through the standard photo-lithography process, and using the 0.5% solution of sodium hydroxide as the developing solution to remove the exposed photoresist and complete the patterning of the photoresist. The pattern of the photoresist obtained is horizontally arranged photoresist stripes with the same spacing.

Further, a specific way for bending the flexible polymer to generate nanoscale cracks on the metal film in the step 4) is as follows: fixing the flexible polymer on a polyimide film, and winding the polyimide film around a steel rod with a certain radius of curvature under the drive of a motor, so that nanoscale cracks parallel to the direction of the steel rod will be generated on the metal film, and different values of the radius of curvature of the steel rod are selected according to different densities of the nanoscale cracks.

Further, the developing solution in the step 5) is a solution of sodium hydroxide with a mass fraction of 0.5%.

Further, the liquid in the step 6) is purified water.

A hydrophone based on nanoscale cracks is prepared by the above-mentioned preparation method. In the hydrophone based on nanoscale cracks prepared by the present invention, the resistance of the metal film with nanoscale cracks on the surface of the flexible polymer will be changed with the variation of low-frequency underwater alternating pressure, and detection of low-frequency underwater sounds can be achieved by connecting a resistance measuring instrument with the electrodes through wires.

Compared with the existing preparation methods of hydrophones, the present invention has the following beneficial effects:
(1) In the present invention, by preparing a layer of metal film with nanoscale cracks on a flexible polymer, a nanoscale crack edge can be connected with an opposite and adjacent crack edge to transfer electrons in the absence of external strain; Under uniaxial tension perpendicular to a crack direction, the gap distance between each pair of crack edges increases until the roughness height of the cracks is exceeded and the crack edges are disconnected. At the same time, due to Poisson's effect, the edges will shrink in a direction perpendicular to the tensile force and be reconnected with opposite and adjacent edges. As the strain increases, the number of connected edges gradually decreases until all edges are disconnected. Therefore, a resistance change is caused by such a “disconnection-reconnection” process in a nanoscale crack hydrophone; through the continuous change of underwater sound pressure, the nanoscale cracks on the surface of flexible polymer will undergo the “disconnection-reconnection” process, thus to achieve ultra-sensitive detection of low-frequency underwater sounds, and expand the detection range of the hydrophone.
(2) The present invention fills the gap in the technical field of hydrophones that no hydrophone is made of flexible polymer.
(3) In addition, the method used in the present invention has a short time consumption, a simple and efficient process flow, and a simple structure, which can significantly improve the resolution of low-frequency underwater sounds and can effectively promote the development of new marine security guarantee technologies and the improvement of detection capabilities in China.

### DESCRIPTION OF DRAWINGS

FIG. 1 is a schematic diagram of depositing a metal film on the surface of a flexible polymer;

FIG. 2 is a schematic diagram of spin coating a photoresist on the surface of the metal film, and patterning the photoresist and the metal film;

FIG. 3 is a schematic diagram of patterning the photoresist on the surface of the metal film again;

FIG. 4 is a schematic diagram of bending the flexible polymer to generate nanoscale cracks on the metal film;

FIG. 5 is a schematic diagram of removing the photoresist on the surface of the metal film;

FIG. 6 is a schematic diagram of bonding the flexible polymer to a PMMA substrate;

FIG. 7 is a schematic diagram of bonding the PMMA substrate to a glass substrate;

FIG. 8 is a three-dimensional structural schematic diagram of a hydrophone based on nanoscale cracks;

FIG. 9 shows resistance variation of the hydrophone at a frequency of 5-20 Hz; FIG. 9 (a) shows resistance variation of the hydrophone at a frequency of 5 Hz; FIG. 9 (b) shows resistance variation of the hydrophone at a frequency of 10 Hz; FIG. 9 (c) shows resistance variation of the hydrophone at a frequency of 15 Hz; FIG. 9 (d) shows resistance variation of the hydrophone at a frequency of 20 Hz.

In the figures: 1 flexible polymer; 2 metal film; 3 photoresist; 4 polyimide film; 5 nanoscale cracks of metal; 6 PMMA; 7 glass sheet.

### DETAILED DESCRIPTION

Specific embodiments of the present invention are described below in detail in combination with the technical solution and accompanying drawings.

As shown in FIG. 1-FIG. 7, a preparation method for a hydrophone based on nanoscale cracks provided by the embodiment is as follows:

Step 1): as shown in FIG. 1, sputtering a layer of metal film 2 (Au) with a thickness of 50 nm on the surface of a flexible polymer 1 (PDMS) with a thickness of 1 mm by a magnetron sputtering method.

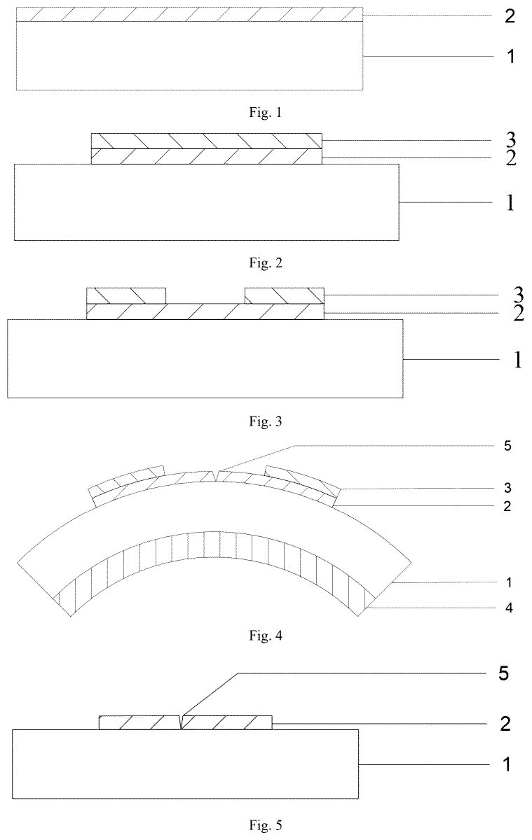

Step 2): as shown in FIG. 2, spin coating a layer of photoresist 3 (BP212) on the surface of the metal film 2, with spin-coating parameters of 1000 rpm and 30 s; placing the spin-coated flexible polymer at room temperature (25′C) for four hours instead of a pre-bake process; using an UV lithography machine to expose the photoresist 3 and achieve patterning, with an exposure time of 222.2 s and a light intensity of 2.7 mW/cm², then conducting development in a solution of sodium hydroxide with a mass fraction of 0.5% for 30 s, and subsequently placing the flexible polymer at room temperature (25C) for four hours instead of a post-bake process: using the patterned photoresist as a mask for wet etching, patterning the metal film 2 by etching in a gold-etching solution with a ratio of I₂:KI:H₂O=1 g:5 g:50 mL for 15 s, and washing with deionized water.

Step 3): as shown in FIG. 3, after changing a photomask, using the UV lithography machine again to expose the photoresist 3 and achieve patterning, with an exposure time of 222.2 s and a light intensity of 2.7 mW/cm², and then conducting development in a solution of sodium hydroxide with a mass fraction of 0.5% for 30 s to achieve the patterning of the photoresist 3 and obtain photoresist stripes with the same spacing.

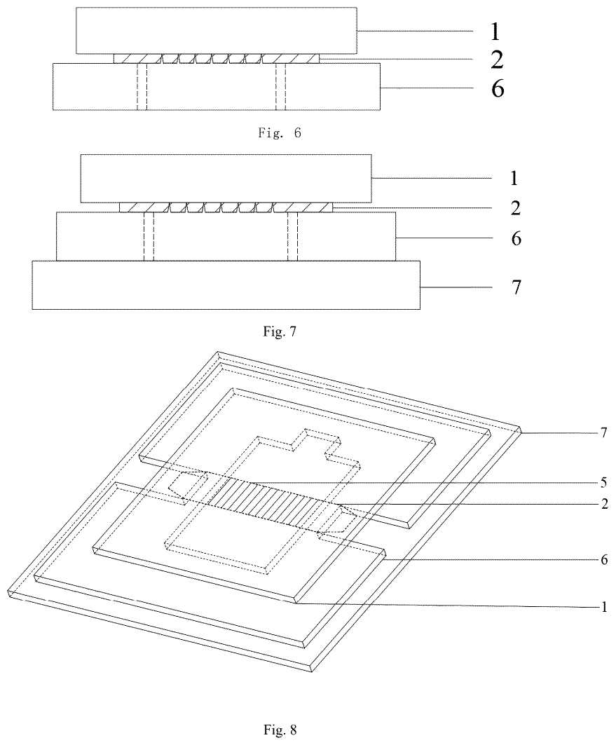

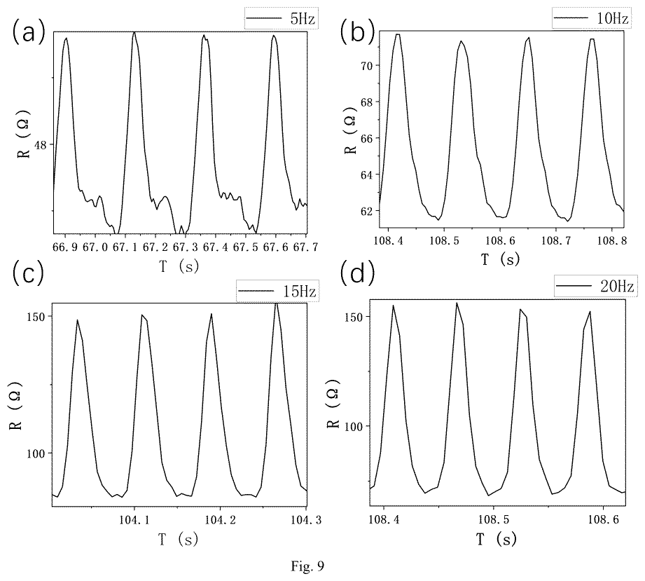

Step 4): as shown in FIG. 4, bending the flexible polymer 1; a specific way is as follows: fixing the patterned flexible polymer on a polyimide film 4 (PI) with a thickness of 75 μm, and winding the polyimide film 4 (PI) around a steel rod with a radius of curvature of 2 mm under the drive of a stepper motor, so that nanoscale cracks 5 parallel to the direction of the steel rod will be generated on the metal film 2 not covered by the photoresist.

Step 5): as shown in FIG. 5, using the UV lithography machine to expose the photoresist 3, and using a solution of sodium hydroxide with a mass fraction of 0.5% to remove the exposed photoresist 3.

Step 6): as shown in FIG. 6 and FIG. 7, cutting a hole penetrating through a PMMA substrate of the same size as the flexible polymer in the center of the substrate by a laser cutting machine, wherein the shape of the hole is not limited; bonding the flexible polymer to one side of the cut PMMA substrate with a residue-free adhesive tape, and reserving an area unbonded for the convenience of subsequent operations: applying the residue-free adhesive tape to the other side of the cut PMMA substrate; bonding a glass sheet to the other side of the PMMA substrate, at which time, a cavity will be formed in the space left after the PMMA substrate between the flexible polymer and the glass sheet is cut; injecting a liquid into the cavity using a syringe through the above-mentioned unbonded area to balance part of the pressure; bonding edges of the unbonded area with the residue-free adhesive tape again to complete the preparation of the hydrophone.

The above embodiments only express the implementation of the present invention, and shall not be interpreted as a limitation to the scope of the patent for the present invention. It should be noted that, for those skilled in the art, several variations and improvements can also be made without departing from the concept of the present invention, all of which belong to the protection scope of the present invention.

1. A preparation method for a hydrophone based on nanoscale cracks, comprising the following steps:
step 1): sputtering a layer of metal film on the surface of a flexible polymer by a thin film deposition method;
step 2): spin coating a layer of photoresist on the surface of the metal film, and patterning the photoresist and the metal film;
step 3): patterning the photoresist on the metal film again according to a required density of nanoscale cracks on the metal film; the pattern of the photoresist obtained is horizontally arranged photoresist stripes with the same spacing, and a neutral layer between part of the flexible polymer with photoresist and part of the flexible polymer without photoresist is at a different level;
step 4): bending the flexible polymer along a direction parallel to the photoresist stripes to generate nanoscale cracks on the metal film of the flexible polymer;
step 5): removing the photoresist on the metal film to obtain a strip-shaped sensing unit with nanoscale cracks, wherein both ends of the strip-shaped sensing unit are provided with electrodes of the sensing unit, and no crack is generated at the electrodes;
step 6): cutting a through hole penetrating through a PMMA substrate of the same size as the flexible polymer in the center of the substrate by a laser cutting machine; bonding the flexible polymer to one side of the cut PMMA substrate with a residue-free adhesive tape, and reserving an area unbonded; bonding a glass sheet to the other side of the PMMA substrate;
forming a cavity at the through hole in the center of the PMMA substrate to be used as a cavity of a hydrophone, and bonding edges of the unbonded area after injecting a liquid into the cavity through the unbonded area to complete the preparation of the hydrophone.

2. The preparation method for a hydrophone based on nanoscale cracks according to claim 1, wherein the substrate of the flexible polymer in the step 1) is made of PDMS, the metal film is made of Au, and the thin film deposition method is a magnetron sputtering method.

3. The preparation method for a hydrophone based on nanoscale cracks according to claim 1, wherein methods for patterning in the step 2) are a standard photo-lithography process and wet etching, and the photoresist is BP212 positive photoresist.

4. The preparation method for a hydrophone based on nanoscale cracks according to claim 1, wherein a method for patterning again in the step 3) is the standard photo-lithography process.

5. The preparation method for a hydrophone based on nanoscale cracks according to claim 1, wherein a specific way for bending the flexible polymer to generate nanoscale cracks on the metal film in the step 4) is as follows: fixing the flexible polymer on a polyimide film, and winding the polyimide film around a steel rod with a radius of curvature under the drive of a motor to generate nanoscale cracks parallel to the direction of the steel rod on the metal film, wherein different values of the radius of curvature of the steel rod are selected according to different densities of the nanoscale cracks.

6. The preparation method for a hydrophone based on nanoscale cracks according to claim 1, wherein a developing solution in the step 5) is a solution of sodium hydroxide with a mass fraction of 0.5%.

7. The preparation method for a hydrophone based on nanoscale cracks according to claim 1, wherein the liquid in the step 6) is purified water.

8. A hydrophone based on nanoscale cracks, wherein the hydrophone is prepared by the preparation method according to claim 1, and detection of low-frequency underwater sounds can be achieved by connecting the hydrophone with a resistance measuring instrument.
